(19) United States
(12) Patent Application Publication
(10) Pub. No.: US 2019/0181302 A1
(43) Pub. Date: Jun. 13, 2019

(54) CONVERTER FOR PARTIAL CONVERSION OF A PRIMARY RADIATION AND LIGHT-EMITTING DEVICE

(71) Applicant: OSRAM Opto Semiconductors GmbH, Regensburg (DE)

(72) Inventor: Peter Brick, Regensburg (DE)

(21) Appl. No.: 16/090,566

(22) PCT Filed: Mar. 24, 2017
(86) PCT No.: PCT/EP2017/057093

§ 371 Date: Oct. 1, 2018

(30) Foreign Application Priority Data
Apr. 1, 2016 (DE) 10 2016 105 988.9

(51) Int. Cl. H01L 33/46; H01L 33/50; H01L 33/40; H01L 33/24

(52) U.S. Cl. CPC H01L 33/46; H01L 33/505; H01L 33/24; H01L 33/405; H01L 33/502

(57) ABSTRACT

A converter for partial conversion of a primary radiation includes a base body containing a luminescence conversion material, and a plurality of structures on a top side of the converter, wherein the structures are formed by elevations of the base body and/or recesses in the base body, and the structures are adapted to reduce a proportion of primary radiation exiting the converter in a main radiation direction (R).

### TECHNICAL FIELD

This disclosure relates to a converter for partial conversion of a primary radiation and a light-emitting device.

### BACKGROUND

DE 102013106799 A1 describes a converter. There is nonetheless a need to provide a converter with which particularly homogeneous mixed light can be generated and a light-emitting device that emits light in a particularly homogeneous manner.

### SUMMARY

I provide a converter for partial conversion of a primary radiation including a base body containing a luminescence conversion material, and a plurality of structures on a top side of the converter, wherein the structures are formed by elevations of the base body and/or recesses in the base body, and the structures are adapted to reduce a proportion of primary radiation exiting the converter in a main radiation direction (R).

I also provide a light-emitting device including a radiation-emitting semiconductor chip that emits primary radiation during operation, and the converter for partial conversion of a primary radiation including a base body containing a luminescence conversion material, and a plurality of structures on a top side of the converter, wherein the structures are formed by elevations of the base body and/or recesses in the base body, and the structures are adapted to reduce a proportion of primary radiation exiting the converter in a main radiation direction (R) that converts a part of the primary radiation in secondary radiation, wherein the converter is arranged on a top side of the semiconductor chip, and mixed radiation is emitted from primary radiation and secondary radiation in operation.

### BRIEF DESCRIPTION OF THE DRAWINGS

FIGS. 1A, 1B, 2A, 2B show schematic sectional views of examples of a converter.

FIG. 3 shows an example of a light-emitting device.

FIGS. 4A and 4B show schematic sectional views of the mode of operation of a converter.

FIGS. 5A, 5B, 5C show graphic depictions of the effect of a converter in a light-emitting device.

### LIST OF REFERENCE NUMERALS

1 carrier

2 semiconductor chip

2a top side

3 wrapping

4 connecting means

5 primary radiation

5′ reflected primary radiation

6 secondary radiation

10 converter

10a top side

11 structure

11a cover surface

11b base area

11c side surface

β angle

P distance

B Extension at the base area

D Extension at the cover surface

R main radiation direction

21 measurement with elevations

22 measurement with recess

23 first comparative measurement

24 second comparative measurement

25 third comparative measurement

### DETAILED DESCRIPTION

My converter is designed for partial conversion of a primary radiation. This means that primary radiation entering the converter is partially converted by the converter into secondary radiation. In this case, the secondary radiation comprises wavelengths greater than wavelengths of the primary radiation. This means the converter is especially designed for so-called “down conversion”. During operation, the converter then emits primary radiation and secondary radiation, which mix in the far field, well at distances to the converter that are large compared to the wavelengths of the emitted light, to form mixed radiation. For example, the far field begins at a distance greater than 10 mm from the converter.

The converter may comprise a base body. The base body contains a luminescence conversion material. The base body may contain or consist of one or more luminescence conversion materials. In particular, it is possible that the base body consists of a ceramic or a semiconducting luminescence conversion material. In a semiconducting luminescence conversion material, it is possible that the converter has grown epitaxially. Furthermore, it is possible that the base body comprises a matrix material such as a plastic material such as silicone or epoxy resin in which particles of at least one luminescence conversion material are incorporated. The luminescence conversion material can then be, for example, a ceramic luminescence conversion material, an organic luminescence conversion material, a semiconductor material or a so-called quantum dot converter (QD-quantum dot).

The converter may comprise a plurality of structures on a top side of the converter. The structures are arranged, for example, on a cover surface of the base body. The cover surface, for example, is a main surface of the base body. This means, the converter is not flat on its top side and is not smooth within the framework of manufacturing tolerance, but a plurality of structures are arranged on the top side of the converter. The structures can be created, for example, by structuring the converter by at least one photographic technique. Furthermore, it is possible that the structures are created by a correspondingly shaped mold by which the converter is injection-molded or injection-extruded, for example. The structures can also be created using stamps.

The structures may be formed by elevations of the base body and/or recesses in the base body. This means, for example, the base body has a plurality of elevations at the top side of the converter formed by material of the base body. For example, the elevations may involve bulges in the base body.

The elevations can border on the top side of the base body, for example, a material that surrounds the converter in use of the converter. The material can be air or a potting material, for example. The converter is bordered on its top side, in particular, on a material that has a smaller refractive index than the converter.

Alternatively or additionally, it is possible that the base body has recesses extending into the base body at the top side of the converter. There is no material of the base body in the area of the recesses. For example, the material of the base body is removed there. The recesses can be filled with a material surrounding the converter. The surrounding material can be air or a potting material, for example. The recesses are then filled with a material with a smaller refractive index than the converter.

The structures may reduce the proportion of primary radiation exiting the converter in a main radiation direction. This means primary radiation enters the converter, for example, at a bottom side opposite the top side. The primary radiation can partially pass through the converter without being converted and exit the converter at the top side of the converter. The main radiation direction from the converter is, for example, the direction perpendicular to a main extension plane of the converter and/or to a main extension plane of the base body of the converter.

The structures are now designed with regard to their shape and/or their size and/or their distribution at the top side of the converter such that the proportion of primary radiation exiting the converter in a main radiation direction is reduced by the structures. In other words, if the structures are not present or if other structures are present, the converter will exit a greater proportion of primary radiation in the main radiation direction than is the case with the structures.

The structures are in particular not designed to increase an exit probability for the primary radiation or for the secondary radiation generated in the converter. Rather, the exit probability for primary radiation and secondary radiation remains substantially the same, this means the exit probability changes by a maximum of +/−10%, in particular by a maximum of +/−5% due to the structures.

The structures are in particular not random roughenings of the base body at the top side of the converter, but preferably structures having a uniform distance from each other and/or having the same shape within the framework of manufacturing tolerance and/or within the framework of manufacturing tolerance have the same size and/or are arranged within the framework of manufacturing tolerance at the grid points of a regular grid. “Within the framework of manufacturing tolerance” may in particular mean that a size deviates at most slightly from a target value, whereby the deviation is not specifically adjusted, but is justified by imponderables in the manufacturing.

My converter may be specified with
a base body containing a luminescence conversion material, and
a plurality of structures on a top side of the converter, wherein
the structures are formed by elevations of the base body and/or recesses in the base body, and
the structures are adapted to reduce the proportion of primary radiation exiting the converter in a main radiation direction.

In particular, the structures are not structures formed with a material deviating from the base body, but the structures are structured in the base body or formed from material of the base body. In other words, the converter consists of the structured base body and has no further layers, which are applied to form the structuring.

The converter described here is based, among other things, on the following consideration: converters for the conversion of primary radiation designed, for example, to convert blue light, can generate secondary radiation that mixes with the primary radiation, for example, to white mixed radiation. The problem usually occurs that the mixed radiation has a significant color variation depending on the viewing angle. Thus, the mixed radiation, for example, in the main radiation direction, with a viewing angle of 0° in the far field, can have an increased proportion of the primary radiation, for example, an increased proportion of blue light. To the side, this means, for example, at a viewing angle of 90° in the far field, the proportion of secondary radiation, for example, of yellow light can then predominate. Overall, no homogeneous radiation depending on the viewing angle is achieved in this way.

The converter described here is based, inter alia, on the idea that a reduction of the proportion of primary radiation that emerges from the converter in a main radiation direction leads to a homogenization of the color impression in the far field since, for example, the proportion of blue light can be reduced at a viewing angle of 0°.

The structures may prevent a part of the primary radiation from exiting the converter. This means that the structures exit less primary radiation from the converter than would be the case without the structures. For example, primary radiation that would leave the converter in the main radiation direction is in particular reflected several times on the structures so that the primary radiation is returned to the base body of the converter. There, for example, this primary radiation is then partially converted into secondary radiation or the primary radiation leaves the converter at its top side facing away from the bottom side.

The structures may direct a part of the primary radiation transversely to the main radiation direction when it leaves the converter. This means, due to the structures, the proportion of primary radiation leaving the converter transverse to the main radiation direction may be greater than would be the case without the structures. In this way, it is possible that the structures in the far field with viewing angles unequal to 0° lead to an increase in the proportion of the primary radiation.

Adjacent structures may have a distance from each other. The structures are arranged, for example, at the corners of a regular grid, for example, a rectangular grid or a triangular grid within the framework of the manufacturing tolerance. The structures each have adjacent structures. The distance that adjacent structures have from each other can then be a mean distance by which the actual distance between adjacent structures of the converter fluctuates, for example, by a maximum of +/−10%, in particular by a maximum of +/−5%.

The distance between adjacent structures is, for example, the distance between the geometric centers of gravity of the structures measured in a plane that runs parallel to the main extension plane of the converter and/or of the base body. The distance is then, for example, the pitch with which the structures are arranged at the top side of the converter.

The distance between the structures is preferably large compared to a wavelength of the primary radiation. For example, the primary radiation has a peak wavelength at which it has a relative or a global maximum. The distance is then particularly large compared to this peak wavelength. In particular, it is possible that the distance between adjacent structures may be at least 10 times, in particular at least 20 times or at least 40 times, as long as a wavelength of the primary radiation, in particular at least 10 times, in particular at least 20 times or at least 40 times, as long as the peak wavelength of the primary radiation. If the primary radiation is, for example, blue light, the distance may be 15 μm to 25 μm, in particular 20 μm.

Preferably, the structures are formed so large that the primary radiation and the secondary radiation are reflected and refracted at them according to the laws of geometric optics.

At least a majority of the plurality of structures may have a base area, a cover surface and at least one side surface that connects the base area and the cover surface and forms an angle with a main extension plane of the converter and/or the base body. “At least a majority of the plurality of structures” means here and in the following that at least 50% of the structures, in particular at least 75% of the structures, preferably all structures have the desired property within the framework of manufacturing tolerance.

For at least a majority of the plurality of structures, the base area may have an extension that corresponds to at least 80% of the distance from adjacent structures. The extension is then, for example, an edge length, in particular the largest edge length of the base areas or a diameter of the base area. The extension of the base area can also correspond to the distance from adjacent structures. This means, in this case, the structures at the top side of the converter directly adjacent so that there is no unstructured area of the base body between the structures.

At least for a majority of the plurality of structures, the cover surface may have an extension corresponding to at most 30% of the extension of the base area. The extension of the cover surface can be, for example, an edge length, in particular the largest edge length of the cover surface, or a diameter of the cover surface. The extension of the cover surface is smaller than the extension of the base area. In particular, the structures have a base area having a larger area content than the cover surface. This means if the structures are elevations, the elevations taper, for example, in the main radiation direction. If the structures are recesses, the structures widen in the main radiation direction.

For at least a majority of the plurality of structures, the angle between the side surface and the main extension plane of the converter and/or the base body may at least in places be at least 60° and at most 80°. Within the framework of the manufacturing tolerance, the side surface preferably runs along a plane so that the angle between the side surface and the main extension plane of the converter and/or the base body along the entire side surface is constant within the framework of the manufacturing tolerance and is at least 60° and at most 80°.

For at least a majority of the plurality of structures, the base area may have an extension corresponding to at least 80% of the distance from adjacent structures, the cover surface has an extension corresponding to at most 30% of the extension of the base area and the angle between the side surface and the main extension plane of the converter is at least 60° and at most 80°. The cover surface has a smaller area content than the base area. In particular, with such structures, it is possible to reduce the proportion of primary radiation that exits from the converter in a main radiation direction.

At least a majority of the plurality of structures may be formed by one of the following geometric bodies: truncated pyramid, truncated cone, inverse truncated pyramid, inverse truncated cone. In other words, the structures within the framework of the manufacturing tolerance can be approximated by one of the mentioned geometric bodies. The geometric body can also have any base areas. This means, for example, the base area of the truncated pyramid may be an n-corner with n>2. Furthermore, the structures in the plan view of the converter can be arranged twisted relative to each other. This means, the structures do not have to be arranged uniformly with the same orientation.

My light-emitting device can be, for example, a light-emitting diode. In particular, the light-emitting device may contain a converter as described herein, this means all of the features disclosed for the converter are also disclosed for the light-emitting device and vice versa.

The light-emitting device may comprise a radiation-emitting semiconductor chip that emits primary radiation during operation. The radiation-emitting semiconductor chip is, for example, a light-emitting diode chip or a laser diode chip. In particular, it is possible that the radiation-emitting semiconductor chip is a so-called surface emitter that emits a majority of the emitting primary radiation through a cover surface on a top side of the semiconductor chip. In addition, the radiation-emitting semiconductor chip may be a so-called volume emitter, in which a reflective material is attached to side surfaces so that a large part of the exiting primary radiation is emitted through a cover surface on a top side of the semiconductor chip.

The light-emitting device may comprise a converter described herein that converts part of the primary radiation into secondary radiation.

The converter may be arranged on the top side of the semiconductor chip. This means, the converter is applied, for example, directly on the top side of the semiconductor chip on this. It is also possible that the converter is attached to the top side of the semiconductor chip by a connecting means, e.g. an adhesive. During operation of the semiconductor chip, the primary radiation then enters the converter at the top side of the semiconductor chip. The bottom side of the converter facing away from the top side faces the semiconductor chip so that the primary radiation enters from the bottom side of the converter. A light emission from the light-emitting device is then preferably carried out mainly at the top side of the converter facing away from the semiconductor chip.

The device may emit mixed radiation of primary radiation and secondary radiation during operation. This means, at least in the far field, the primary radiation and the secondary radiation mix to the mixed radiation. Due to the converter described herein, it is possible that the color homogeneity of the mixed radiation as a function of the viewing angle improves compared to light-emitting devices without a converter described herein, this means more homogeneous.

The light-emitting device may be specified with
a radiation-emitting semiconductor chip that emits primary radiation during operation, and
a converter that converts a part of the primary radiation in secondary radiation, wherein the converter is arranged on a top side of the semiconductor chip, and
mixed radiation is emitted from primary radiation and secondary radiation during operation.

The mixed radiation may be white light. For example, the mixed radiation may be warm white or cold white light.

In the light-emitting device, the converter is specifically structured on its top side so that an emission of primary radiation in the main radiation direction is slightly reduced. The proportion of primary radiation in the main radiation direction can be achieved in particular by two effects that can be generated by the converter described here.

On the one hand, a reflection of the primary radiation on side surfaces of the structures and on the cover surface of the structure can lead to the primary radiation being directed back into the converter.

On the other hand, a reflection of primary radiation on a side surface of the structure as well as a Fresnel reflection on a side surface of the structure and a refraction of primary radiation exiting at the side surface of the structure can lead to an increased lateral emission, transversely to the main radiation direction. This results in a light-emitting device in which the color homogeneity of the mixed radiation is increased with respect to the viewing angle in the far field. In this way, the mixed light, for example, no longer appears bluish in the main radiation direction, but white and the mixed light at large viewing angles, for example, no longer appears yellowish, but white.

The light-emitting device may comprise a wrapping laterally surrounding the semiconductor chip and the converter, wherein the wrapping is reflective for primary radiation and secondary radiation and located in direct contact with the semiconductor chip and the converter in places. The wrapping is, for example, a plastic material such as silicone or epoxy resin filled with radiation-scattering and/or radiation-reflecting particles. For example, the plastic material is filled with titanium dioxide particles. The particles can give the wrapping a white color impression. Primary radiation incident on the wrapping or secondary radiation incident on the wrapping is reflected back at the wrapping, for example, into the semiconductor chip or into the converter so that finally, for example, only light is exited at the top side of the converter. In addition, it is possible for the wrapping to completely cover side surfaces of the semiconductor chip and the converter and, for example, it is flush with the converter at its top side or protrudes laterally beyond the converter in the framework of the manufacturing tolerance.

My converters and light-emitting devices are explained in more detail on the basis of examples and the corresponding figures.

Identical, similar or identical acting elements are provided in the figures with the same reference numerals. The figures and the proportions of the elements shown in the figures with each other are not to be regarded as true to scale. Rather, individual elements may be oversized for better representability and/or better understanding.

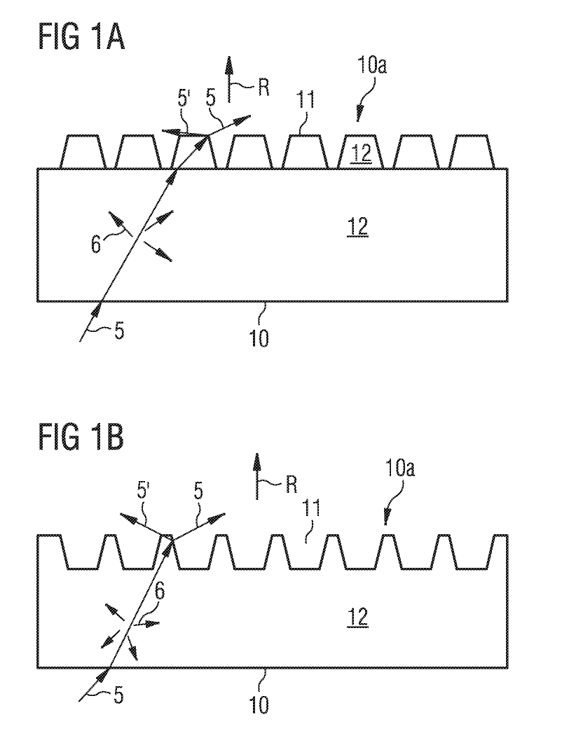

The schematic sectional views of FIGS. 1A and 1B show examples of a converter. The converter 10 is provided for partial conversion of a primary radiation 5. The primary radiation is partially converted in the converter 10 to secondary radiation 6. The electromagnetic radiation 5, 6 leaves the converter 10 at its top side in the main radiation direction R, which runs perpendicular to a main extension plane of the converter 10.

The converter 10 comprises a base body 12 that contains or consists of a luminescence conversion material. For example, in the base body 12 are luminescence conversion materials, for example, particles of a luminescence conversion material introduced into a matrix that may be formed with silicone. Furthermore, it is possible for the conversion element 10 to be a conversion element that consists, for example, of a ceramic or a semiconducting luminescence conversion material.

The converter comprises a plurality of structures 11 on the top side 10a of the converter, wherein the structures in the example of FIG. 1A are formed by elevations of the base body 12. In the example of FIG. 1B, the structures are formed by recesses in the base body 12.

The structures 11 are designed to reduce the proportion of primary radiation 5 that exits from the converter 10 in the main radiation direction R.

The structures may, for example, be structures formed within the framework of the manufacturing tolerance by one of the following geometric bodies: truncated pyramid, truncated cone, inverse truncated pyramid, inverse truncated cone.

In the converters as shown in FIGS. 1A and 1B, the structures 11 are formed uniformly with regard to their shape, size and arrangement. This means the structures 11 are arranged, for example, at the grid points of a regular grid and they have the same size and the same shape within the framework of the manufacturing tolerance.

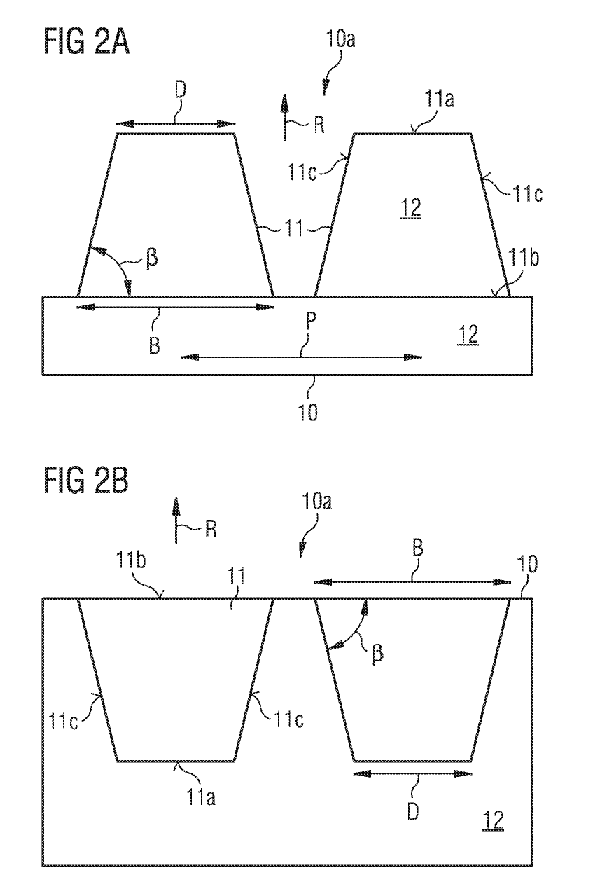

In connection with the schematic sectional views of FIGS. 2A and 2B, the preferred dimensions of the structures 11 are explained in more detail. In the example of FIG. 2A, the structures 11 are formed by truncated pyramids. The structures 11 have a cover surface 11a, a base area 11b and side surfaces 11c that connect the cover surface 11a to the base area 11b.

The structures 11 have on their base area 11b an extension B that, for example, is the diameter of the base area of the structure 11. The cover surface 11a has an extension D, that is, for example, the diameter of the cover surface 11a. The base area 11b of each structure is larger than the cover surface 11a of each structure.

The side surface 11c extends transversely to the main extension plane of the converter 10 and encloses an angle β with it. The base area 11b and the cover surface 11a extend within the framework of the manufacturing tolerance parallel to the main extension plane of the converter 10.

Adjacent structures 11 have the distance P from each other, that is, for example, the distance of the geometric center of gravity of adjacent structures 11 in a plane parallel to the main extension plane of the converter 10.

For converters 10, it is preferred that the structures 11 have the following dimensions:

60°≤β≤80°,

0.8P≤B≤P,

0<D≤0.3B

The same applies to the structures 11 formed as recesses as shown in FIG. 2B.

The distance P between adjacent structures is preferably large relative to the wavelength of the primary radiation 5 and may be 20 μm, for example.

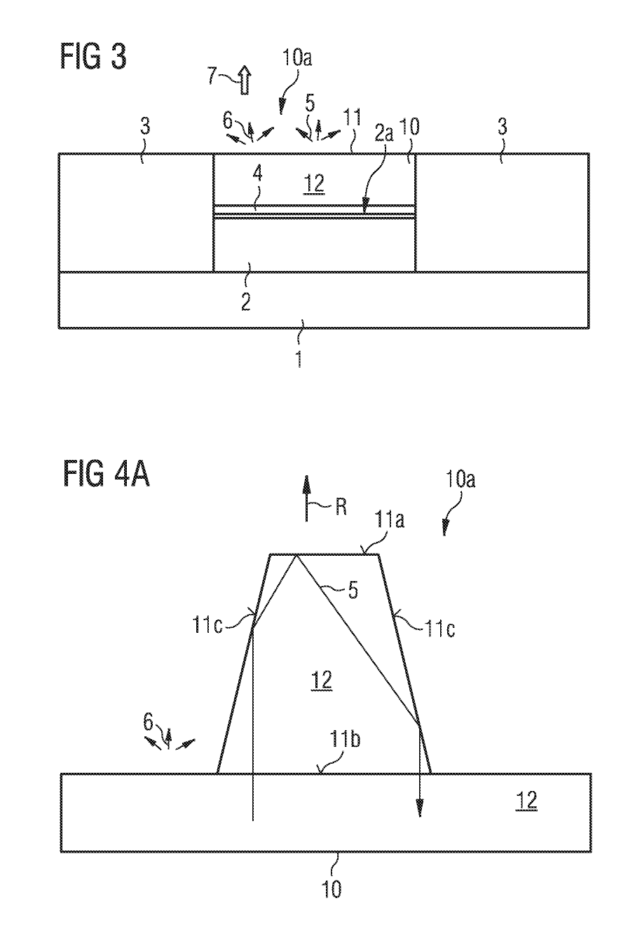

In connection with the schematic sectional view of FIG. 3, an example of a light-emitting device is explained in more detail. The light-emitting device comprises, for example, a carrier 1, which is, for example, a connection carrier designed for the electrical connection of the radiation-emitting semiconductor chip 2 arranged on its top side.

The radiation-emitting semiconductor chip 2 is formed, for example, by a surface-emitting light-emitting diode chip. A converter 10 is arranged on a top side 2a of the semiconductor chip 2 having the base body 12 and the structures 11 structured into the base body and/or out of the base body 12.

Between the semiconductor chip 2 and the converter 3, a connecting means 4 for mechanical and optical connection of semiconductor chip 2 and converter 3 may be arranged. For example, the connecting means 4 is an adhesive.

The wrapping 3 is arranged laterally around semiconductor chip 2 and converter 3, which can be formed white and reflective, for example.

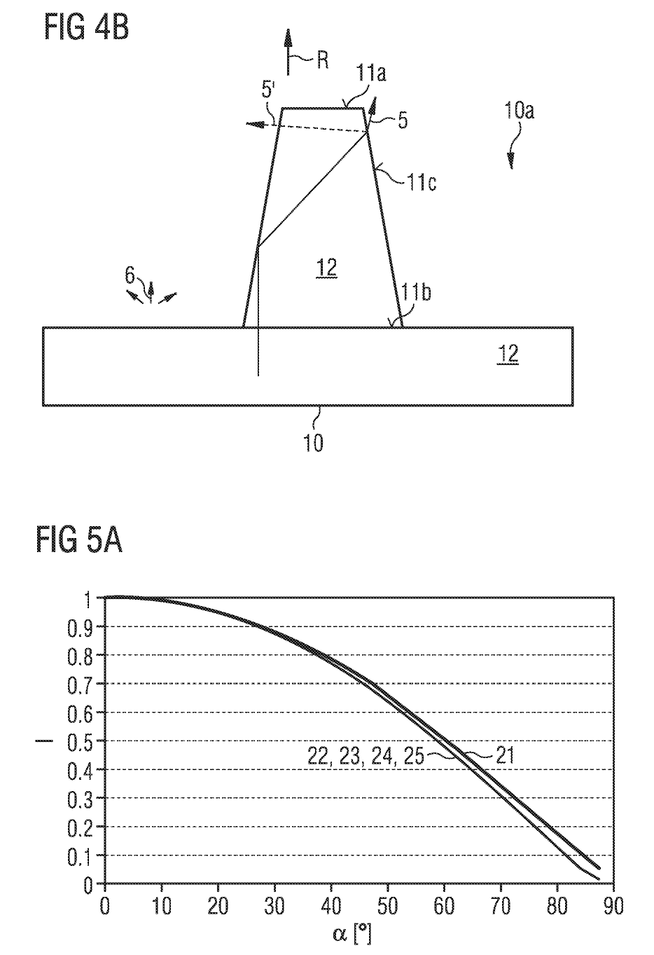

In connection with the schematic sectional views of FIGS. 4A and 4B, the functionality of a converter is explained in more detail. In this case, the mode of operation is explained on the basis of a structure 11, which is formed as an elevation from the base body 12.

The converter 10 is characterized by a reduced radiation of primary radiation 5 in the main radiation direction R. In this case, this is achieved in two different ways. The mode of operation of the converter is explained by structures 11 designed as elevations, wherein corresponding effects are also achieved with the structures explained, for example, in FIGS. 1B and 2B formed as recesses in the base body 12.

FIG. 4A schematically shows that primary radiation 5 is reflected, for example, totally reflected at a first side surface 11c of the structure 11 and hits the cover surface 11a, where again a reflection in the direction of a second side surface 11c of the structure 11 occurs, from where the primary radiation 5 is reflected back into the converter 10. This means that there is a reflection of primary radiation that has entered the structure 11 in the main radiation direction R by multiple reflection. This reduces the proportion of primary radiation leaving the converter 10 in the main radiation direction R at the top side 10a. A part of the primary radiation 5 can exit at the cover surface 11a or the side surface 11c as a refracted primary radiation 5 towards the side (not shown).

Such primary radiation 5 that does not penetrate into the structure 11 in the direction of the main radiation direction R can, for example, be reflected on a first side surface 11c, as shown in FIG. 4B. The primary radiation 5 then hits, for example, on a second side surface 11c, where it is partially refracted and laterally decoupled. However, due to the large angle at which the primary radiation hits the side surface 11c and the high refractive index difference between the converter 10 and its surroundings, a part of the primary radiation 5′ is Fresnel-reflected and then decoupled to the side as reflected primary radiation 5′. Also, in this way, the proportion of primary radiation 5, which is radiated in the main radiation direction R, is reduced, whereas the proportion of primary radiation exited transversely to the main radiation direction R is increased.

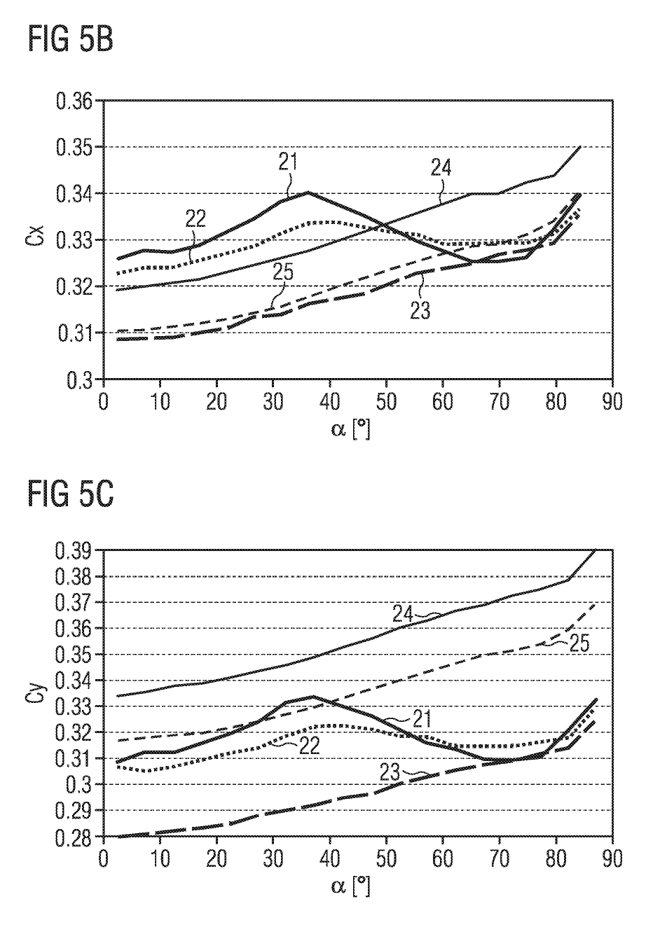

The effect of a converter 10 in a light-emitting device is explained on the basis of the graphic depictions of FIGS. 5A, 5B, 5C. It is assumed that the converter 10 has an average thickness of 200 μm and a reflective potting with titanium dioxide particles forms the wrapping 3 around the chip 2 and the converter 3. The structuring are truncated pyramids, which are arranged at a distance P of 20 μm from each other.

In the following, curves are shown, which are provided with the reference numerals 21, 22, 23, 24, 25.

The curve 21 refers to a measurement in which the structures 11 are formed as elevations. The angle β is chosen to be 72°, the extension B of the base area 11b is 19 μm, and the extension D of the cover surface 11a is 1.9 μm.

The curve 22 relates to measurements for a converter 10, in which the structures are formed as recesses having an angle β of 70°. B is 17 μm for the recesses and D is 1.7 μm.

The curves 23, 24, 25 relate to light-emitting devices without a structured converter, which are used for comparison.

In the graphic representation of FIG. 5A, the intensity I normalized to 1 is first shown as a function of the viewing angle a in the far field (“far field angle”).

It turns out that the radiation characteristic, that is to say the intensity depending on α, is hardly influenced by the structure 11. In particular, in the curve 22, which shows measurements for recesses, no difference to conventional light-emitting devices is recognizable. This means, my converters can replace conventional converters without affecting the radiation characteristics, which allows them to be used in existing products without, for example, having to adapt downstream optics.

FIG. 5B shows the Cx component in the CIE-xy color space of a color location measurement of the light emitted by the light-emitting devices under consideration as a function of α. FIG. 5C shows the Cy component in the CIE-xy color space. As can be seen from the graphic depiction of FIGS. 5B and 5C, the variation of the color location for light-emitting devices with converters described here (compare curves 21 and 22) is significantly reduced compared to conventional light-emitting devices with conventional converters. The fluctuation in the Cx component is less than 0.02, and the fluctuation in the Cy component is less than 0.03.

My converters and light-emitting devices are not limited by the description based on the examples. Rather, this disclosure includes any novel feature as well as any combination of features, which in particular includes any combination of features in the appended claims, even if the feature or combination itself is not explicitly stated in the claims or examples.

The priority of DE 102016105988.9 is claimed, the subject matter of which is incorporated herein by reference.

1.-10. (canceled)

11. A converter for partial conversion of a primary radiation comprising:
a base body containing a luminescence conversion material, and
a plurality of structures on a top side of the converter, wherein
the structures are formed by elevations of the base body and/or recesses in the base body, and
the structures are adapted to reduce a proportion of primary radiation exiting the converter in a main radiation direction (R).

12. The converter according to claim 11, wherein the structures are adapted to prevent a part of the primary radiation from leaving the converter.

13. The converter according to claim 11, wherein the structures are adapted to direct a part of the primary radiation transversely to the main radiation direction (R) as it exits the converter.

14. The converter according to claim 11, wherein adjacent structures have a distance (P) from each other which is large compared to a wavelength of the primary radiation.

15. The converter according to claim 11, wherein adjacent structures have a distance (P) from each other at least 10 times as large as a wavelength of the primary radiation.

16. The converter according to claim 11, wherein at least a majority of the plurality of structures has a base area, a cover surface and at least one side surface connecting the base area and the cover surface and at least in places including an angle (β) with a main extension plane of the converter,
the base area has an extension (B) corresponding to at least 80% of the distance (P) from adjacent structures,
the cover surface has an extension (D) not more than 30% of the extension (B) of the base area, and
the angle (β) between the side surface and the main extension plane of the converter is at least 60° and at most 80°.

17. The converter according to claim 11, wherein at least a majority of the plurality of structures is formed by one of truncated pyramid, truncated cone, inverse truncated pyramid, and inverse truncated cone.

18. A light-emitting device comprising:
a radiation-emitting semiconductor chip that emits primary radiation during operation, and
the converter according to claim 11 that converts a part of the primary radiation in secondary radiation, wherein
the converter is arranged on a top side of the semiconductor chip, and
mixed radiation is emitted from primary radiation and secondary radiation in operation.

19. The light-emitting device according to claim 18, wherein the mixed radiation is white light.

20. The light-emitting device according to claim 18, further comprising a wrapping that laterally surrounds the semiconductor chip and the converter, wherein the wrapping for the primary radiation and the secondary radiation reflects and is in direct contact with the semiconductor chip and the converter in places.
